(19) United States
(12) Patent Application Publication
(10) Pub. No.: US 2010/0097771 A1
(43) Pub. Date: Apr. 22, 2010

(54) CIRCUIT BOARD ASSEMBLY

(75) Inventor: CHE-WEN HSU, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: CHI MEI COMMUNICATION SYSTEMS, INC., Tu-Cheng City (TW)

(21) Appl. No.: 12/486,872

(22) Filed: Jun. 18, 2009

(30) Foreign Application Priority Data
Oct. 21, 2008 (CN) 200810305072.1

(51) Int. Cl. H05K 1/18

(52) U.S. Cl. 361/748

(57) ABSTRACT

A circuit board assembly used in a portable electronic device includes a circuit board, a duplexer mounted on the circuit board, and a shielding member defining a hole corresponding to the duplexer therein. The shielding member is mounted on the circuit board and surrounds portions of the duplexer, and the hole exposes portions of the duplexer from the shielding.

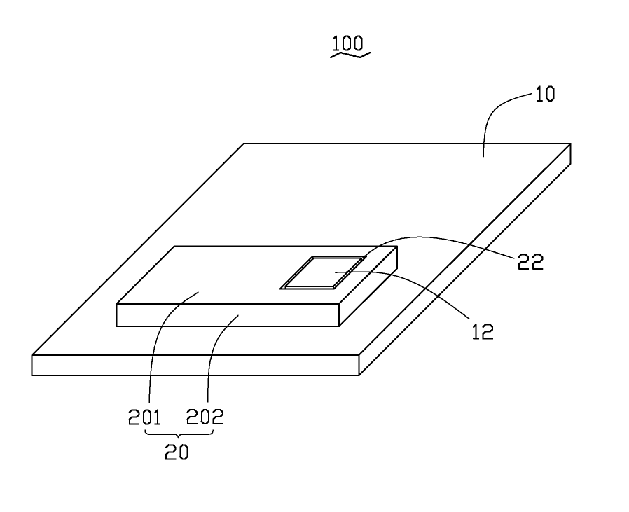

### BACKGROUND

1. Technical Field

The present disclosure relates to circuit board assemblies, and particularly to a circuit board assembly with improved single tone desensitization (STD) performance.

2. Description of Related Art

Shielding members (e.g., a can made of metal) are widely used in portable electronic devices, having the function of wireless communication such as mobile phones, laptop computers or personal digital assistants (PDA). In a portable electronic device, an inner circuit board of the portable electronic device is generally covered by a shielding member to protect the circuit board from outside interference and prevent electromagnetic waves escaping the circuit board.

However, some portable electronic devices, such as code division multiple access (CDMA) mobile phones, use duplexers. When a duplexer mounted in an inner circuit board of a portable electronic device is entirely covered by a shielding member, the working signals of the duplexer may be reflected by the shielding member. Thus, working of the duplexer may be disturbed and the STD performance of the portable electronic device may be worsened, which may deteriorate the communication quality of the portable electronic device.

Therefore, there is room for improvement within the art.

### BRIEF DESCRIPTION OF THE DRAWINGS

Many aspects of the present circuit board assembly can be better understood with reference to the following drawings. The components in the various drawings are not necessarily drawn to scale, the emphasis instead being placed upon clearly illustrating the principles of the present circuit board assembly.

The FIGURE is a schematic view of a circuit board assembly, according to an exemplary embodiment.

### DETAILED DESCRIPTION

The FIGURE schematically shows a circuit board assembly 100 according to an exemplary embodiment, which is used in a portable electronic device (not shown) having the function of wireless communication, such as a mobile phone, a laptop computer, or a personal digital assistant (PDA). The circuit board assembly 100 includes a circuit board 10, a duplexer 12, and a shielding member 20. The duplexer 12 is mounted on the circuit board 10. The shielding member 20 is mounted on the circuit board 10 and covers a whole or a part of the circuit board 10 to shield electronic components on the circuit board 10 requiring electromagnetic shielding, including, e.g., portions of the duplexer 12.

In this embodiment, the shielding member 20 is a can made of conductive materials, such as metal. The shielding member 20 includes a top board 201 and a side frame 202 corresponding to the top board 201. The top board 201 defines a hole 22 therein, wherein the position, shape and size of the hole 22 correspond to the position, shape, and size of the duplexer 12. The side frame 202 is perpendicularly connected to the periphery of the top board 201 to surround the top board 201. A width of the side frame 202 is appreciably larger than a thickness of the duplexer 12 and other electronic components (not shown) on the circuit board 10, such that the top board 201 can cover the portions of the duplexer 12 and other electronic components when the side frame 202 is connected to the circuit board 10.

In assembly, the top board 201 is positioned parallel to the circuit board 10 to cover the electronic components on the circuit board 10 requiring electromagnetic shielding, e.g., portions of the duplexer 12, and the side frame 202 is positioned to surround the electronic components. The duplexer 22 is also aligned with the hole 22 such that a top surface of the duplexer 22 is exposed from the shielding by the hole 12. Finally, the side frame 202 is fixed on the circuit board 20, thus the circuit board assembly 100 is completed and can be installed in the portable electronic device.

When the portable electronic device works, the shielding member 20 shields the electronic components on the circuit board 10 to protect the electronic components from outside interference and prevent the electromagnetic waves escaping the electronic components.

Furthermore, when the duplexer 12 works, since the top surface of the duplexer 22 is exposed through the shielding by the hole 22, the working signals of the duplexer 12 can transmit from the hole 22 and are not reflected by the top board 201. Therefore, working of the duplexer 12 is facilitated and the single tone desensitization (STD) performance of the portable electronic device is improved. In an experiment, the circuit board assembly 100 is used in a code division multiple access (CDMA) mobile phone, and the STD performance of the CDMA mobile phone increases about 2.5 dB. Thus, the communication quality of the CDMA mobile phone is improved.

Understandably, the position, number, size and shape of the hole 22 can be changed. In the foregoing embodiments, the top board 201 defines only one hole 22, and the position, shape and size are similar to the position, shape and size of a top surface of the duplexer 12. Thus, the STD performance of the portable electronic device using the circuit board assembly 100 can be improved, and the shielding member 20 can still provide good electromagnetic shielding.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1 A circuit board assembly used in a portable electronic device, comprising:
a circuit board;
a duplexer mounted on the circuit board;
a shielding member defining a hole corresponding to the duplexer; wherein the shielding member is mounted on the circuit board, surrounds portions of the duplexer, and the hole exposes portions of the duplexer from the shielding.

2. The circuit board assembly as claimed in claim 1, wherein the shielding cover shields at least a portion of the circuit board.

3. The circuit board assembly as claimed in claim 1, wherein the shielding member is a can made of conductive material.

4. The circuit board assembly as claimed in claim 3, wherein the shielding member includes a top board and a side frame connected to the top board, and the top board is positioned parallel to the circuit board to cover the circuit board and the side frame is fixed to the circuit board.

5. The circuit board assembly as claimed in claim 4, wherein the hole is defined in the top board.

6. The circuit board assembly as claimed in claim 1, wherein the shape and size of the hole are similar to the shape and size of a top surface of the duplexer.

7. The circuit board assembly as claimed in claim 6, wherein the duplexer is aligned with the hole.
